(19) United States
(12) Patent Application Publication
(10) Pub. No.: US 2024/0110835 A1
(43) Pub. Date: Apr. 4, 2024

(54) CORROSION RESISTANT COATING FOR TEMPERATURE PROBES

(71) Applicant: UCHICAGO ARGONNE, LLC, Chicago, IL (US)

(72) Inventors: Sumit Bhattacharya, Darien, IL (US); Cari A. Launiere, Bolingbrook, IL (US); Abdellatif M. Yacout, Naperville, IL (US)

(21) Appl. No.: 18/374,851

(22) Filed: Sep. 29, 2023

Related U.S. Application Data
(60) Provisional application No. 63/411,967, filed on Sep. 30, 2022.

(51) Int. Cl. G01K 7/02; C23C 14/06; C23C 14/14; C23C 14/22; G01K 7/36; G01K 11/22; G01K 11/3206

(52) U.S. Cl. CPC G01K 7/02; C23C 14/067; C23C 14/14; C23C 14/22; G01K 7/36; G01K 11/22; G01K 11/3206

(57) ABSTRACT

A corrosion resistant coating suitable for use in harsh environments, such as for protecting a temperature probe for continuous use in the Hall-Héroult process can include at least one first layer comprising a metal boride and at least one second layer comprising a metal interposed between the substrate and the at least one metal boride layer. The coating can have a thickness of less than 10 micrometers.

### CROSS-REFERENCE TO RELATED APPLICATION

The benefit of priority to U.S. Provisional Patent Application No. 63/411,967 filed Sep. 30, 2022, is hereby claimed and the disclosure is incorporated herein by reference in its entirety.

### STATEMENT OF GOVERNMENT SUPPORT

This invention was made with government support under Contract No. DE-AC02-06CH11357 awarded by the United States Department of Energy to UChicago Argonne, LLC, operator of Argonne National Laboratory. The government has certain rights in the invention.

### FIELD

The disclosure is directed to a corrosion resistant coating for temperature probes, and more particularly, to a corrosion resistant coating for ultrasonic transducer probes for a Hall-Héroult process vessel.

### BACKGROUND

The Hall-Héroult process is the major industrial process for aluminum smelting. It involves the electrolytic reduction of aluminum oxide in a molten cryolite bath. The corrosivity of molten cryolite salt is so great that the only material suitable for use as the process vessel is a frozen layer of the salt itself. Temperature monitoring is still carried out manually by an operator who periodically opens the lid of each cell (of which there are up to 1000 in a single facility) and dips an insertion pyrometer into the electrolyte to measure the temperature. No sensor for continuous in-situ monitoring of any kind have been successfully deployed in the Hall-Héroult process because no materials can withstand the extreme corrosivity of the molten cryolite. Platinum-rhodium thermocouples are currently used in research sectors of the aluminum industry, but they are too expensive relative to their lifespan for operational settings.

The main corroding agents for molten cryolite salt based on Na₂AlF₆ chemistry in the Hall-Héroult process include fluorine ions, CO₂, NaF, Na, Na₂O, and Al₂O₃.

The most common high temperature corrosion barrier materials are Ni based alloys, Cr based alloys, alumina-silicate composites, cerium/yttrium stabilized composites, ZrSiO₄, and SiC—SiO composites. However, none of these materials can perform in the harsh environment of molten cryolite. Even though these materials perform well in high temperature air or steam environments, they deteriorate very rapidly when exposed to fluorine radicals. When such materials are exposed to fluorine, they easily form low melting fluoride compounds, resulting in poor mechanical integrity of the barrier layers. The layers either break part exposing the metal underneath or dissolve into the molten bath of cryolite.

Any material that is thermodynamically unstable in the cryolite environment will either selectively leech from the barrier material (such as Ni from NiFe alloy coatings) or react to form an oxide, mixed fluoride/oxide, or a fluoride. For example, Ti turns into TiO₂, which then turns to TiOₓF_{y}. This behavior also occurs for highly stable oxides, as fluorine is a stronger oxidant and at high temperature can easily replace oxygen from the oxide barrier coating.

Sodium and NaF readily react or diffuse into the surface of conventional barrier materials. This can happen even when the barrier material is cable of forming stable fluorides. For example, even though YF₃ forms a very stable high melting fluoride, when it is exposed to about 28 mol % NaF, a compound which melts at about 640° C. is formed.

### SUMMARY

There is a need for real-time temperature monitoring in the aluminum smelting process. Feedback of this information could allow for real-time process optimization that could drastically improve the efficiency of this energy intensive process, which consumes about 300 trillion BTU world-wide each year. To achieve such real-time monitoring, a corrosion resistant coating capable of protecting probes in the molten cryolite environment is needed.

A multilayer corrosion resistant coating in accordance with the disclosure is a multilayer coating, which includes at least one first layer comprising a metal boride and at least one second layer comprising a metal that is a strong fluoride former, such as lanthanides and transition metals. The multilayer coating has a coating thickness of less than 10 micrometers and at least one second layer is arranged between the substrate and the at least one first layer.

### BRIEF DESCRIPTION OF THE DRAWINGS

FIG. 1 is a cross-sectional image of a corrosion resistant coating in accordance with the disclosure.

FIG. 2 is a photograph of cryolite exposure testing set-up used in testing the corrosion resistant coating in accordance with the disclosure.

FIGS. 3A to 3E are images showing analysis of an uncoated SS304 sample after exposure to cryolite for 72 hours.

FIGS. 4A to 4D are images showing analysis of an SS304 coated with a corrosion resistant coating in accordance the disclosure, after exposure to cryolite for 72 hours.

FIG. 5 is a graph showing change in weight as a function of cryolite exposure time for two corrosion resistant coatings in accordance with the disclosure coated on SS304 and an uncoated SS304 sample.

### DETAILED DESCRIPTION

Coatings of the disclosure are multilayer coatings that include at least one first layer comprising a metal boride disposed on at least one second layer, with at least one second layer being disposed between a first layer and the substrate to be coated. The at least one second layer comprises a metal that is a strong fluoride former, such as a lanthanide or transition metal. The coatings of the disclosure can advantageously have a thickness of less than 10 micrometers, which can be beneficial for sensor sensitivity and response time. The coatings of the disclosure are advantageously stable in cryolite environments, making them useful as corrosion resistant coatings for components used in the Hall-Héroult process

Corrosion resistant materials of the disclosure are capable of withstanding a cryolite environment. They exhibit low solubility in cryolite melts and high physical and thermal stability at operational temperatures. The corrosion resistant materials of the disclosure are stable in the presence of both oxygen and fluorine radicals, as well as metal radicals, such as Al and Na. While borides, such as TiB₂/TiBC and ZrB₂/ZrBC compounds have been determined to be stable against cryolite, they suffer from thermal expansion mismatch against the substrate upon which they are coated. Conventionally, these metal borides are either deposited in-situ in the cryolite environment or they are pre-deposited over carbon electrodes to protect them from corrosion. However, the mismatch in the coefficients of thermal expansion between these conventional coatings and the substrate results in the coatings cracking. A proposed solution to such cracking problems was to reduce stress through depositing the ZrB₂ in-situ during the electrolysis process using pre-dissolved ZrO₂ and B₂O₃ in the cryolite melt. However, the resulting coating layers are generally porous and cryolite diffuses inside to the substrate being protected. Further, such process of deposition is not possible for application to a transducer probe because the transducer probe is not part of the electrode system.

In contrast to conventional methods, the coatings of the disclosure utilize a multi-layer approach in which the metal borides are deposited over target substrate with a flexible metal coating made from a strong fluoride former, such as lanthanide elements and transition metals. The coatings of the disclosure demonstrate reduced residual stress over the boride layers. Additionally, the coatings of the disclosure are more resistant to spallation of the coating as a result of having a layered composite structure. Coatings of the disclosure can also be advantageously thin while being able to remain mechanically and chemically stable in the cryolite environment. For example, the coatings can have a thickness of less than 10 micrometers. This is particularly advantageous when the coating application is a transducer probe. Thick coatings over a transducer probe are anticipated to adversely change the receiving and release frequencies, which complicates data acquisition.

The first layer can include one or more of ZrB₂, TiB₂, LaB₆, LaBₓ+LaC_{y} (where 0<x<6 and 0<y<2), TiBₓ+TiC (where 0<x<2), including stoichiometric, sub-stoichiometric, and super-stoichiometric forms thereof. Sub-stoichiometric forms are those in a metal ratio is lower against the boron concentration, while a super-stoichiometric form is one in which the metal ratio is higher against the boron concentration. The metal boride layer can be co-deposited mixed borides. Any combination of the metal borides listed herein can be co-deposited as mixed borides. For example, co-deposited mixed borides can include or more of ZrB₂—TiB₂, LaB₆—ZrB_{2′} and LaB₆—TiB₂, including stoichiometric, sub-stoichiometric, and super-stoichiometric forms thereof.

The first layer can include one or more of sub-stoichiometric forms of ZrB₂, TiB₂, and LaB₆. The sub-stoichiometric metal boride can be co-deposited mixed borides. Co-deposited sub-stoichiometric mixed co-deposited mixed borides can include or more of ZrB₂—TiB₂, LaB₆—ZrB₂, LaB₆—TiB₂, and TiB₂C—LaB₆C.

The second layer can comprise include metals which are strong fluoride formers. Lanthanide elements and transition metals are strong fluoride formers. For example, the second layer can include one or more of La, Ce, Pr, Nd, Pm, Sm Eu, Gd, Tb, Dy, Ho, Er, Tm, Yb, Lu, Zr, Ti, Mo, and Br.

The second layer can also include metal alloys which are strong fluoride formers. Lanthanide elements and transition metal alloys are also strong fluoride formers. For example, the metal alloy can be comprised of one or more of La, Ce, Pr, Nd, Pm, Sm Eu, Gd, Tb, Dy, Ho, Er, Tm, Yb, Lu, Zr, Ti, Mo, and Br.

For example, corrosion resistant coatings can include ZrB₂ as the first layer and Zr as the second layer; ZrB₂—TiB₂ as the first layer and Zr as the second layer, TiB₂ as the first layer and Ti as the second layer, ZrB₂ as the first layer and Ti as the second layer; LaB₆—ZrB₂ as the first layer and Ti as the second layer, LaB₆—TiB₂ as the first layer and Ti as the second layer.

In coatings have more than two layers, the first layers can each be the same metal boride composition or different metal boride compositions. The second layers can each be the same metal or can be different metals.

The corrosion resistant coating can have one or more alternating layers of the first and layers. The coating is applied such that a second layer is disposed on the substrate, intervening between the substrate and the first layer. The corrosion resistant coating can have 2 to 50 layers, 2 to 10 layers, 15 to 35 layers, or 30 to 50 layers. Other suitable numbers of layers include about 2, 4, 6, 8, 10, 12, 14, 16, 18, 20, 22, 24, 26, 28, 30, 32, 34, 36, 38, 40, 42, 44, 46, 48, and 50 layers.

Each layer of the coating can have a thickness of about 50 nm to about 200 nm, about 75 nm to about 125 nm, or about 50 nm to about 100 nm. Other suitable thicknesses include about 50, 60, 70, 80, 90, 100, 110, 120, 130, 140, 150, 160, 170, 180, 190, and 200 nm, and any intervening values and ranges defined there between.

The layers of the corrosion coating of the disclosure can be individually deposited using physical vapor deposition. For example, plasma assisted physical vapor deposition can be used for depositing the metal and/or metal boride layers.

The substrate can be, metallic or ceramic. For example, the substrate can be a probe. For example, the probe can be a temperature probe. The substrate can be a substrate subjected to a cryolite environment for which corrosion resistance is needed.

Diffusion or interfacial mixing of the components of the first and second layers can occur in the coatings of the disclosure. In such coating, the first layer may comprise the metal of the second layer and/or the second layer may comprise the metal boride of the first layer. Such intermixing can occur, for example, from long term high temperature exposure or during the coating process. For example, a coating formed with a first layer composition of sub stoichiometric ZrB₂ and a second layer composition of Ni, can result in a coating that has a first layer comprising ZrBₓ+Ni.

The probe can be an ultrasonic waveguide, for example a waveguide in an ultrasonic time-domain reflectometer (TDR) temperature sensor. Ultrasonic TDR temperature sensors are based on the principle that the speed of sound is inversely proportional to temperature in most materials. An ultrasonic TDR sensor includes a rod of waveguide material connected to an ultrasonic piezoelectric or electromagnetic transceiver. The sensor detects temperature in multiple zones using discontinuities on the waveguide, which can include notches, soldering joints, or bends on the probe. The transceiver transmits an ultrasonic surface flexure wave to the probe, which is reflected at each surface discontinuity. The roundtrip transit time to and from the transceiver is dependent on the distance traveled and the material temperature.

The probe can be an optical fiber. For example, Fiber Bragg grating sensors measure temperature based on the thermal expansion of the fiber. Thermal expansion shifts the Bragg wavelength, which is detected with an optical spectrum analyzer. The corrosion resistant coating can be applied to a sheath over the fiber in such sensors.

The probe can be a thermocouple and the thermocouple can be coated with the corrosion resistant coating.

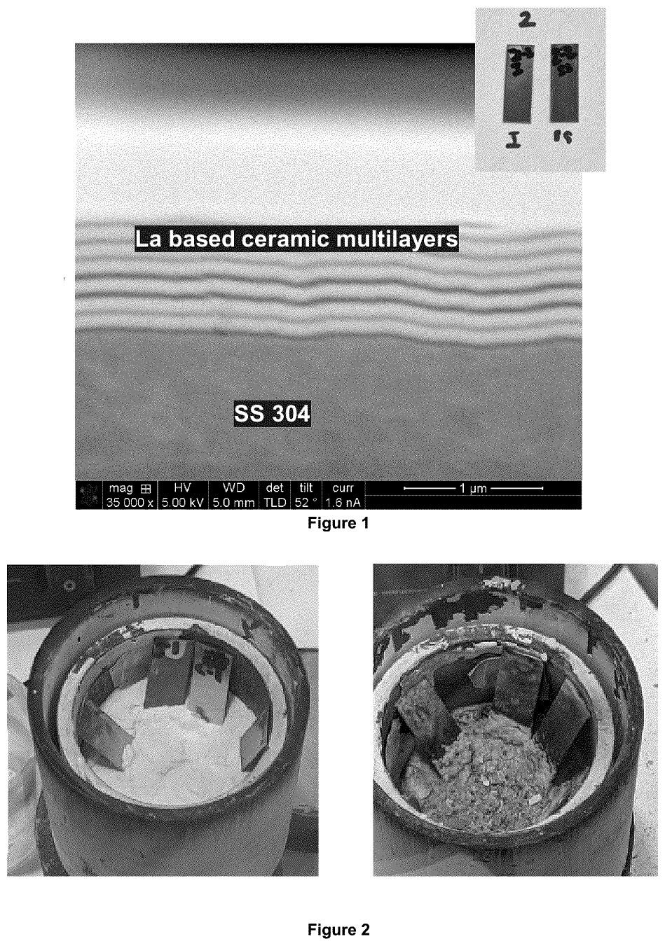

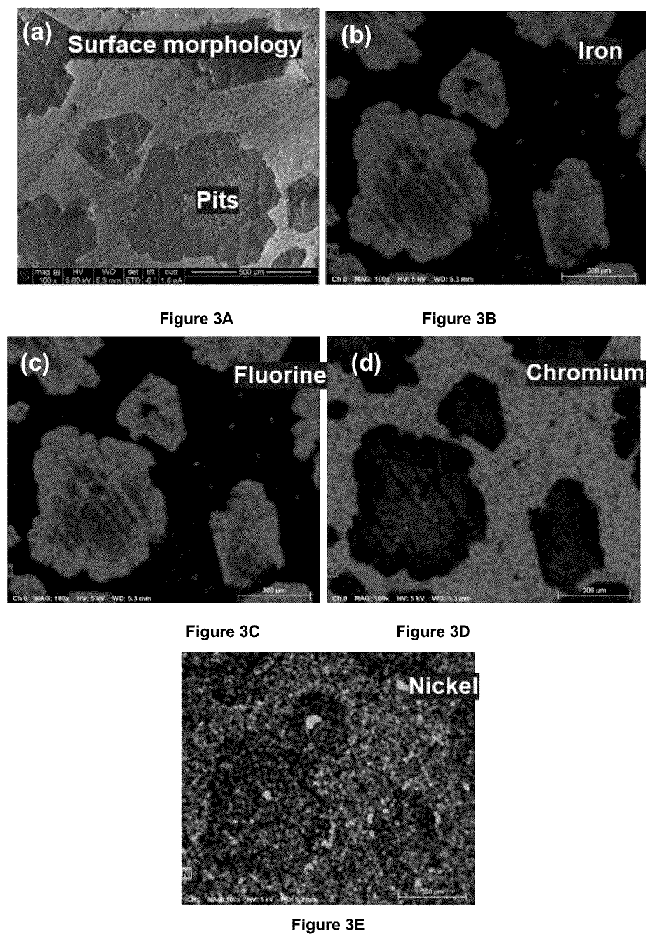

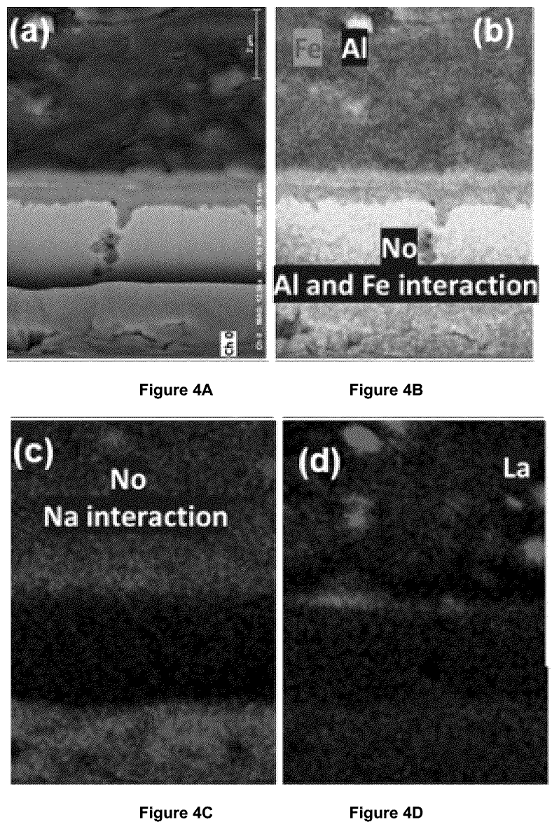

Referring to FIG. 1, a coating in accordance with the disclosure is shown illustrating the multilayer structure. Corrosion studies were performed using the La-based multilayer coating in accordance with the disclosure shown in FIG. 1. The coating was formed on an SS304 stainless steel. FIG. 2 shows is a schematic illustration of the cryolite exposure testing set-up. The uncoated SS304 was exposed to the cryolite environment for 72 hours. Referring to FIGS. 3A to 3D, the exposed uncoated SS304 had large surface pits, with selective leaching of Cr, exposing iron to the cryolite. The led to iron fluoride formation. The SS304 uncoated was found to be insufficient for operation in the molten cryolite. Referring to FIGS. 4A-4D, in contrast the SS304 substrate coated with the La-based coating of the disclosure showed no interaction between the AlF₃/NaF and the SS304, demonstrating that the coating remained protective throughout the exposure period. FIG. 4A shows a cross-sectional image of the coated substrate after exposure, showing a distinct interface remained between the coating layers and the underlying SS304 substrate.

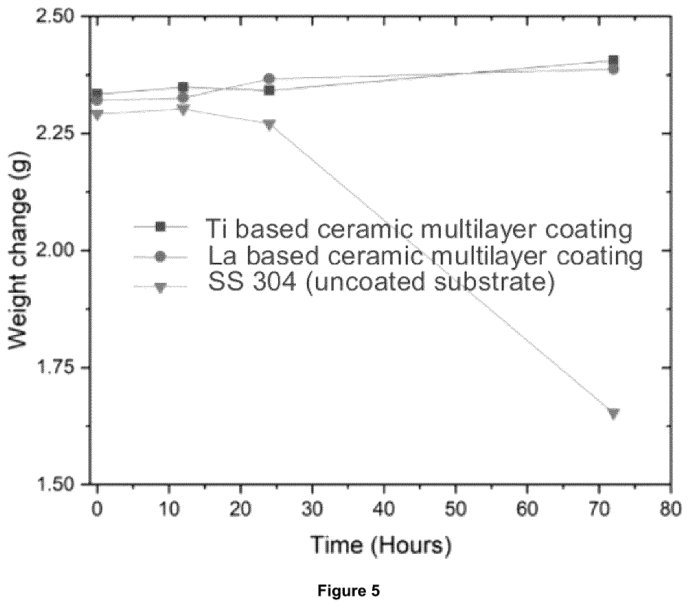

Similar exposure testing was also performed using a Ti-based coating in accordance with the disclosure on an SS304 substrate. FIG. 5 illustrates the weight change after 72 hours exposure in the molten cryolite. As can be seen, the coatings of the disclosure remained stable throughout the exposure period.

The foregoing description is given for clearness of understanding only, and no unnecessary limitations should be understood therefrom, as modifications within the scope of the disclosure may be apparent to those having ordinary skill in the art.

All patents, patent applications, government publications, government regulations, and literature references cited in this specification are hereby incorporated herein by reference in their entirety. In the case of conflict, the present description, including definitions, will control.

Throughout the specification, where the compounds, compositions, methods, and/or processes are described as including components, steps, or materials, it is contemplated that the compounds, compositions, methods, and/or processes can also comprise, consist essentially of, or consist of any combination of the recited components or materials, unless described otherwise. Component concentrations can be expressed in terms of weight concentrations, unless specifically indicated otherwise. Combinations of components are contemplated to include homogeneous and/or heterogeneous mixtures, as would be understood by a person of ordinary skill in the art in view of the foregoing disclosure.

What is claimed is:

1. A corrosion resistant multilayer coating for coating a substrate, comprising:
at least one first layer comprising a metal boride; and
at least one second layer comprising a metal selected from lanthanides and transition metals, wherein
the multilayer coating has a thickness of less than 10 micrometers, and
at least one of the at least one second layer is disposed between the substrate and the at least one first layer.

2. The coating of claim 1, wherein the first layer comprises one or more of ZrB₂, TiB₂, LaB₆, LaBₓ+LaC_{y} (where 0<x<6 and 0<y<2), and TiBₓ+TiC (where 0<x<2).

3. The coating of claim 1, wherein the at least one first layer comprises one or more of sub-stoichiometric or super stoichiometric forms of ZrB₂, TiB₂, LaB₆, LaBₓ+LaC_{y} (where 0<x<6 and 0<y<2), TiBₓ+TiC (where 0<x<2) in which a metal ratio can be lower or higher against the boron concentration.

4. The coating of claim 1, wherein the at least one first layer comprises co-deposited mixed borides.

5. The coating of claim 5, wherein the co-deposited mixed borides comprise ZrB₂—TiB₂, LaB₆—ZrB₂, LaB₆—TiB₂, or TiB₂C—LaB₆C.

6. The coating of claim 5, wherein the co-deposited mixed borides comprise of sub or super stoichiometric compositions of ZrB₂—TiB₂, LaB₆—ZrB₂, LaB₆—TiB₂, TiB₂C—LaB₆C.

7. The coating of claim 1, wherein the at least one second layer comprises Ni, Zr, Mo, La, Ti, alloys thereof, or combinations thereof.

8. The coating of claim 1, wherein the multilayer coating comprises:
ZrB₂ as the first layer and Zr as the second layer;
ZrB₂—TiB₂ as the first layer and Zr as the second layer;
TiB₂ as the first layer and Ti as the second layer;
ZrB₂ as the first layer and Ti as the second layer;
LaB₆—ZrB₂ as the first layer and Ti as the second layer;
LaB₆—TiB₂ as the first layer and Ti as the second layer;
TiB₂C as the first layer and Ni as the second layer; or
LaB₆C as the first layer and Ni as the second layer.

9. The coating of claim 1, wherein each layer is about 100 nm thick.

10. The coating of claim 1, wherein the at least one first layer is deposited by plasma assisted physical vapor deposition.

11. The coating of claim 1, wherein the at least one second layer is deposited by plasma assisted physical vapor deposition.

12. A probe coated with the coating of claim 1.

13. The probe of claim 13, wherein the probe is an ultrasonic waveguide.

14. The probe of claim 13, wherein the probe is an optical fiber and the coating is disposed on a sheath surrounding the optical fiber.

15. The probe of claim 13, wherein the probe is a thermocouple.

16. The probe of claim 13, wherein the probe is stable against exposure to molten cryolite.

17. The probe of claim 13, wherein the probe is capable of continuous temperature monitoring in a Hall-Héroult process.
